(19) United States
(12) Patent Application Publication
(10) Pub. No.: US 2005/0035369 A1
(43) Pub. Date: Feb. 17, 2005

(54) Structure and method of forming integrated circuits utilizing strained channel transistors

(76) Inventors: Chun-Chieh Lin, Hsin-Chu (TW); Wen-Chin Lee, Hsin-Chu (TW); Yee-Chia Yeo, Hsin-Chu (TW); Chenming Hu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/729,092

(22) Filed: Dec. 5, 2003

Related U.S. Application Data
(60) Provisional application No. 60/495,584, filed on Aug. 15, 2003.
(60) Provisional application No. 60/497,819, filed on Aug. 26, 2003.

(51) Int. Cl. H01L 31/0328

(52) U.S. Cl. 257/194

(57) ABSTRACT

A semiconductor device or circuit is formed on a semiconductor substrate with first and second semiconductor materials having different lattice-constants. A first transistor includes a channel region formed oppositely adjacent a source and drain region. At least a portion of the source and drain regions are formed in the second semiconductor material thereby forming lattice-mismatched zones in the first transistor. A second component is coupled to the transistor to form a circuit, e.g., an inverter. The second component can be a second transistor having a conductivity type differing from the first transistor or a resistor.

### CROSS-REFERENCE TO RELATED APPLICATIONS

This application claims the benefit of U.S. Provisional Application No. 60/495,584 filed on Aug. 15, 2003, and U.S. Provisional Application No. 60/497,819, filed Aug. 26, 2003, which applications are hereby incorporated herein by reference.

The following U.S. patents and/or commonly assigned patent applications are hereby incorporated herein by reference:

| Patent or | | | |
|---|---|---|---|
| Ser. No. | Filing Date | Issue Date | Attorney Docket No. |
| 10/379,033 | Feb. 28, 2003 | — | TSM03-0050 |
| 10/667,871 | Sep. 22, 2003 | — | TSM03-0553 |
| 10/641,813 | Aug. 15, 2003 | — | TSM03-0554 |
| 10/628,020 | Jul. 25, 2003 | — | TSM03-0555 |
| 10/627,218 | Jul. 25, 2003 | — | TSM03-0556 |
| — | — | — | TSM03-0615 |

### TECHNICAL FIELD

The present invention relates generally to semiconductor devices, and more particularly to an inverter and integrated circuits utilizing strained channel transistors.

### BACKGROUND

Size reduction of the metal-oxide-semiconductor field-effect transistor (MOSFET), including reduction of the gate length and gate oxide thickness, has enabled the continued improvement in speed performance, density, and cost per unit function of integrated circuits over the past few decades. Integrated circuits typically include many, e.g., millions, of these transistors. As a result, there are ongoing attempts to continue improving these devices.

One semiconductor circuit that is commonly used in integrated circuits is an inverter. FIG. 1a shows the schematic of an inverter circuit 104, and FIG. 1b shows the cross-section 106 of the transistors 100, 102 constituting the inverter circuit 104. An inverter 104 is used to invert a logic state. A complementary metal-oxide-semiconductor (CMOS) inverter includes a PMOS transistor 100 and a NMOS transistor 102 as shown in FIGS. 1a and 1b. In operation, when the input terminal V_{IN} is charged to the supply voltage V_{DD}, i.e., logic state ‘1’, the NMOS transistor 102 turns on, and the voltage of the output terminal V_{OUT} goes to ground, i.e., logic state ‘0’. When the input terminal V_{IN} is grounded, the NMOS transistor 102 turns off and the PMOS transistor 100 turns on, causing the output terminal V_{OUT} to be driven to a V_{DD} level, i.e., logic state ‘1’.

Referring to FIG. 1b, the drains 108 of the PMOS 100 and NMOS 102 transistors are both coupled to an output terminal V_{OUT}, and their gate electrodes 110 are connected to an input terminal V_{IN}. The source 112 of the PMOS 100 transistor is connected to the supply voltage V_{DD}, and the source 114 of the NMOS 102 transistor is connected to ground.

A load capacitance, denoted as C_{L}, represents a lumped capacitance that exists between the output terminal V_{OUT} and the ground. Since the load capacitance C_{L} must be charged or discharged before the logic swing is complete, the magnitude of C_{L} has a large impact on the performance of the inverter 104.

The propagation delay tp characterizes how quickly an inverter 104 responds to a change in its input, and is given by
tₚ=C_{L}·V_{DD}/Iₐᵥ (Eq. 1)
where Iₐᵥ is the average current during the voltage transition, and V_{DD} is the supply voltage. There is a propagation delay t_{pHL} associated with the NMOS transistor 102 discharging current as shown in FIG. 1d, and a propagation delay t_{pLH} associated with the PMOS transistor 100 charging current as shown in FIG. 1c. The average of t_{pHL} and t_{pLH} represents the overall inverter 104 delay. To reduce the inverter 104 delay, the values of t_{pHL} or t_{pLH}, or both have to be reduced.

Delay values in an inverter and other semiconductor circuits can be reduced by increasing carrier mobility. Significant mobility enhancement has been reported for both electrons and holes in bulk transistors using a silicon channel under biaxial tensile strain. The strain contributed by the high stress film is understood to be uniaxial in nature with a direction parallel to the source-to-drain direction. However, uniaxial tensile strain improves electron mobility while uniaxial compressive strain improves hole mobility. Ion implantation of germanium may be used selectively to relax the strain.

### SUMMARY OF THE INVENTION

Preferred embodiments of the present invention teach a structure and method of forming integrated circuits utilizing strained channel transistors. For example, an improved invention can be achieved by including a strained channel transistor.

According to a first embodiment, a first transistor is formed in a semiconductor substrate and includes a source and a drain region oppositely adjacent a channel region. A first gate dielectric covers the first channel region and a first gate electrode covers the first gate dielectric. At least a portion of the source and drain regions are formed in the second semiconductor material thereby forming first and second lattice-mismatched zones. A second transistor is formed in the semiconductor substrate and has a conductivity type different than the first transistor.

In accordance with another preferred embodiment of the present invention, an inverter includes a strained transistor and another semiconductor component. The inverter is formed in a semiconductor substrate that includes first and second semiconductor materials. The first semiconductor material has a lattice constant that is different from a lattice constant of the second material. The source, drain and channel regions of the strained transistor are formed in the semiconductor substrate. At least a portion of the first source and drain regions are formed in the second semiconductor material thereby forming lattice-mismatched zones in the first transistor. The inverter also includes a load element formed in the semiconductor substrate and coupled to the first transistor. The load element may be any semiconductor device, such as a second transistor, a second strained transistor, or a resistor, for example.

An advantage of a preferred embodiment of the present invention is reduced load capacitance on the output of the device. A reduction in load capacitance reduces the time required for a device output voltage to rise and fall, increasing the speed of the device.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1a is a prior art schematic diagram of an inverter with a lumped capacitance between the output terminal and ground;

FIG. 1b shows a prior art cross-sectional view of transistors forming an inverter;

FIGS. 1c and 1d show characteristics of the operation of an inverter;

FIGS. 2a-2c show a first, second and third embodiment of the present invention;

FIGS. 3a-3d illustrate alternate embodiment structures;

FIG. 4 illustrates another alternate preferred embodiment structures;

FIGS. 5a-5c show semiconductor circuits that represent further embodiments of the present invention;

FIGS. 6a-6h show steps for a preferred embodiment method of manufacturing a semiconductor device; and

FIGS. 7a-7c show an alternate embodiment inverter.

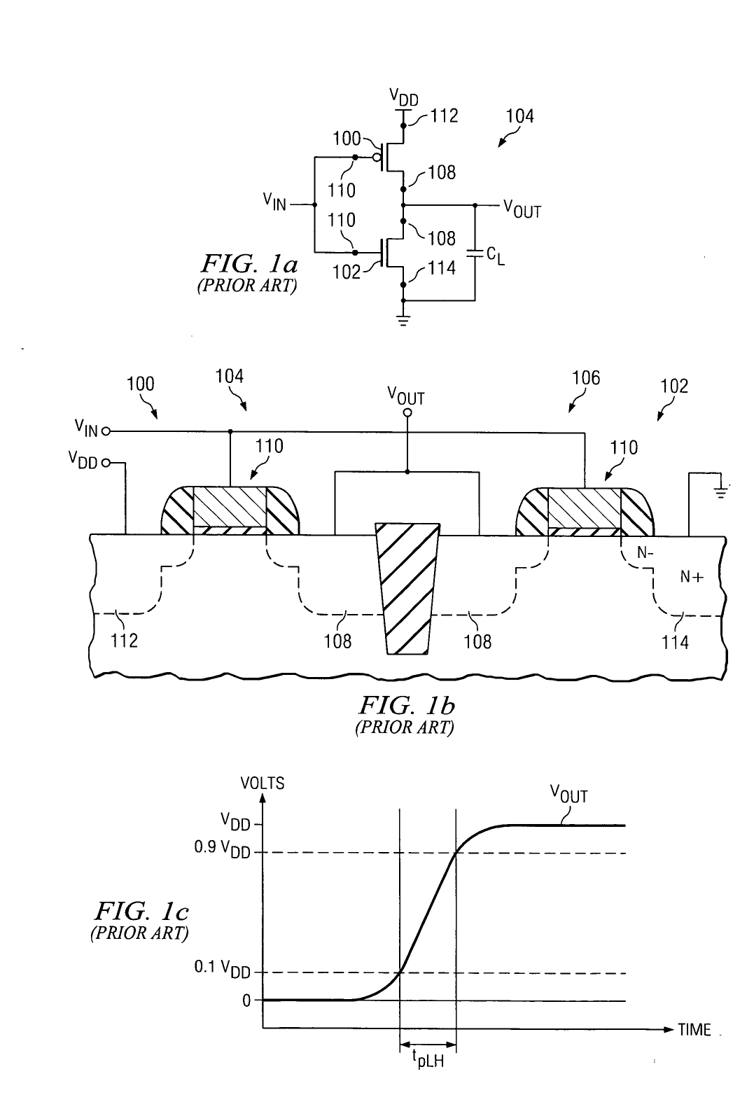

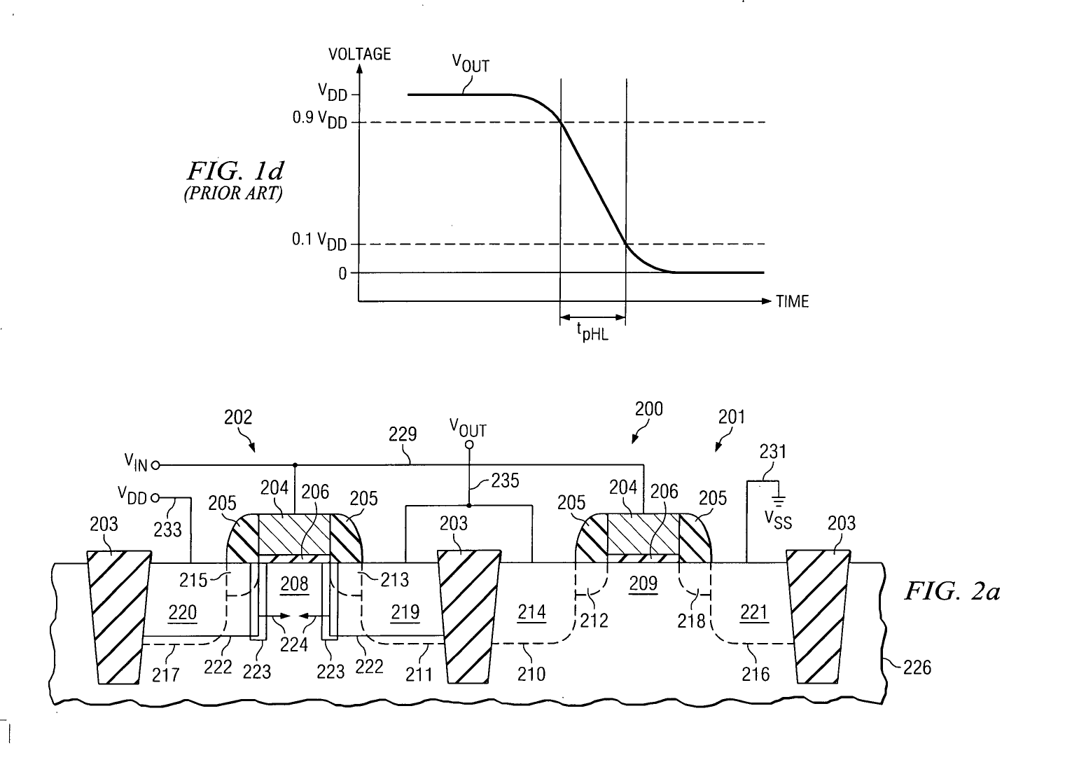

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. This invention teaches the enhancement of circuit performance by the introduction of strain in one or more transistor channel regions of a semiconductor circuit. The specific embodiments discussed are merely illustrative of specific ways to make and use the invention, and do not limit the scope of the invention.

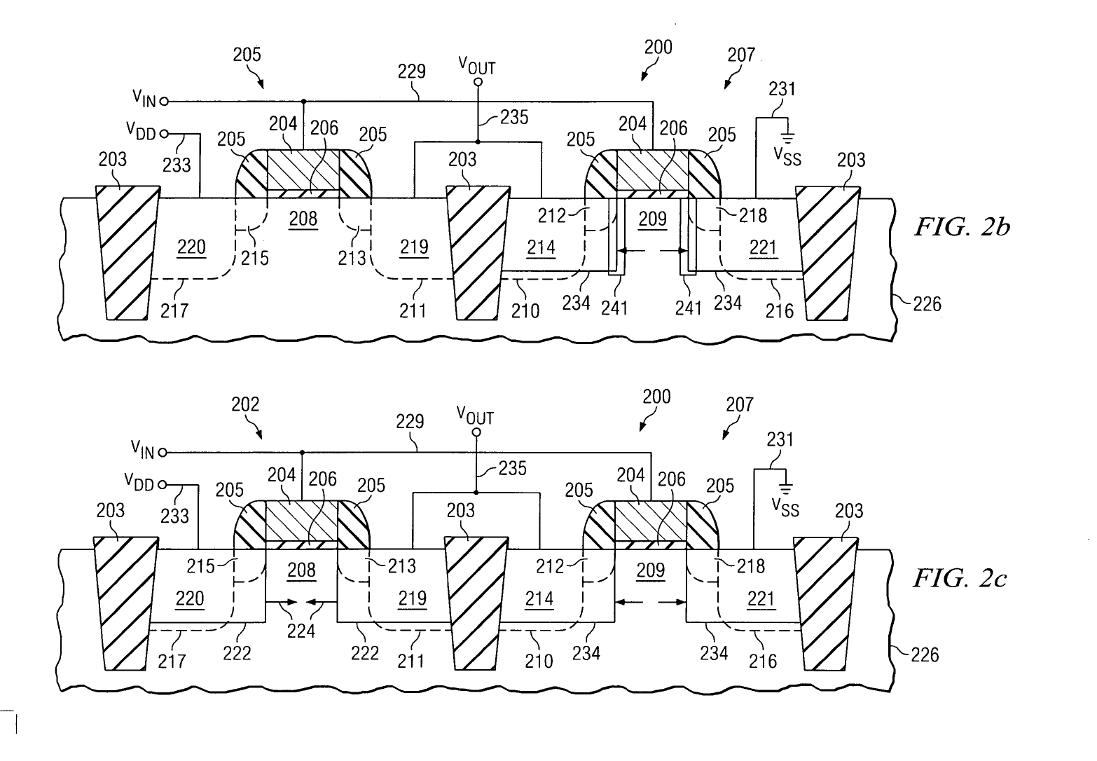

The present invention relates to the field of semiconductor devices and circuits, and more specifically, to the manufacture of inverter circuits using strained channel field effect transistors. A first, second and third preferred embodiment of the present invention are shown in FIGS. 2a-2c, referred to collectively as FIG. 2.

A first semiconductor material 226 shown in FIG. 2 is a semiconductor substrate, preferably formed from silicon. However, it is understood that other substrates comprising compoundsemiconductor substrates, e.g., gallium arsenide, or alloy semiconductor, e.g., silicon-germanium, may be used. The starting material may also be a semiconductor-on-insulator (SOI) substrate, such as a silicon-on-insulator substrate. The starting material may also include an epitaxially grown semiconductor layer and/or a doped region within a semiconductor layer, e.g., a triple well structure.

FIG. 2a shows a cross-sectional view of transistors 201/202 constituting an inverter 200. A PMOS strained transistor 202 and an NMOS transistor 201 are disposed within an active area bounded by isolation structures 203. The strained PMOS transistor 202 has a channel region 208, and the NMOS has a channel region 209 having a different conductivity type than the PMOS channel region.

The gate electrodes 204, are formed from one of doped poly-crystalline silicon or poly-crystalline silicon germanium, and are placed above gate dielectrics 206. In other embodiments, the gate electrode 204 can be made from one or more of metals, metallic silicides, metallic nitrides, or conductive metallic oxide. In the preferred embodiment, the electrode 204 comprises poly-crystalline silicon. Metals such as molybdenum, tungsten, titanium, tantalum, platinum, and hafnium may be used as the portion of the top electrode 204. Metallic nitrides may include, but are not restricted to, molybdenum nitride, tungsten nitride, titanium nitride, and tantalum nitride. Metallic silicides may include, but will not be restricted to, nickel silicide, cobalt silicide, tungsten silicide, titanium silicide, tantalum silicide, platinum silicide, and erbium silicide. Conductive metallic oxides may include, but will not be restricted to, ruthenium oxide and indium tin oxide.

Gate spacers 205, are formed from a dielectric, e.g., silicon dioxide and silicon nitride, and are formed on the sides of the gate electrodes 204. The gate dielectrics 206 are formed above the channel regions 208/209 and below the gate electrodes 204. The gate dielectrics 206 comprise a material such as silicon oxide, silicon oxynitride, or silicon nitride for example. The gate dielectric could also be a high-k dielectric, preferably having a permittivity greater than about 8. This dielectric can be one or more of aluminum oxide (Al₂O₃), hafnium oxide (HfO₂), hafnium oxynitride (HfON), hafnium silicate (HfSiO₄), zirconium oxide (ZrO₂), zirconium oxynitride (ZrON), zirconium silicate (ZrSiO₄), yttrium oxide (Y₂O₃), lanthanum oxide (La₂O₃), cerium oxide (CeO₂), titanium oxide (TiO₂), tantalum oxide (Ta₂O₅), or combinations thereof.

In the preferred embodiment, the high-k dielectric is hafnium oxide. The silicon equivalent oxide thickness (EOT) of the dielectric 206 is preferably smaller than about 50 angstroms, more preferably smaller than about 20 angstroms, and even more preferably smaller than about 10 angstroms. The physical thickness of the dielectric 206 may be smaller than about 100 angstroms, more preferably smaller than about 50 angstroms, and even more preferably smaller than about 20 angstroms.

The NMOS drain region 210 includes a drain extension region 212 coupled to a deeper drain region 214 and the PMOS drain region 211 includes a drain extension region 213 coupled to a deeper drain region 219. The NMOS source region 216 comprises a source extension region 218 coupled to a deeper source region 221 and the PMOS source region 217 comprises a source extension region 215 coupled to a deeper source region 220.

The first, second and third preferred embodiments shown in FIGS. 2a-2c further comprise interconnects 229, 231, 233, 235 that are shown schematically. The interconnects must be formed from metal or metal-alloys such as aluminum, copper, tantalum, titanium, molybdenum, tungsten, platinum, aluminum, hafnium, ruthenium, or any combination thereof, for example. For example, conductive plugs, e.g., tungsten, could make contact with the silicon regions while a conductive line (e.g., copper) couples the plugs to one another and to the supply nodes.

In the specific example shown, an interconnect 235 couples the PMOS drain 211 and the NMOS drain 210 and carries the voltage output V_{OUT} of the inverter circuit. Another interconnect 233 provides a voltage supply V_{DD} to the PMOS source region 217. A third interconnect 231 couples a voltage supply V_{SS} to the NMOS source region 216. In the preferred embodiment, V_{SS} is a grounded connection and V_{DD} supplies a voltage level in the range of about 0.3 to about 5 volts (e.g., less than about 1.8 volts). The gate electrodes 204 are coupled to one another and to a voltage supply V_{IN} by a fourth interconnect 229.

An inverter circuit comprises the elements described above. If a-voltage level equal, or nearly equal to the voltage level of V_{DD} is provided by the voltage source V_{IN}, the voltage level of V_{OUT} will be equal, or nearly equal, to the voltage level of V_{SS}. Conversely, if a voltage level equal, or nearly equal to the voltage level of V_{SS} is provided by VIN, V_{OUT} will have a voltage level equal, or nearly equal, to the voltage level of V_{DD}.

In the preferred embodiment, the channel region 208 comprises crystalline silicon. Crystalline silicon has a diamond lattice structure and a natural lattice constant of about 5.431 angstroms. The natural lattice constant is the lattice constant of the material in its relaxed or bulk equilibrium state.

In the first preferred embodiment, a strained channel PMOS transistor 202 is coupled to an NMOS transistor 201 to form an inverter, as shown in FIG. 2a. A first stressor 222 occupies a region proximate the sides of the PMOS channel 208 and comprises a non-negligible portion of the PMOS source 217 and PMOS drain 211 regions. Lattice-mismatch zones 223 define the junction of the first and second semiconductor materials 206 and 222 in the PMOS transistor 202. It is noted that the figures are not necessarily drawn to scale. In fact, in the preferred embodiment, the stressor has a thickness of about a few hundred angstroms, while the source and drain region may have a depth of up to a thousand angstroms or more. Therefore, the stressor usually forms a small portion of the source/drain regions.

The second semiconductor material 222 comprises an alloy semiconductor such as silicon-germanium, which typically has a natural lattice constant in the range of about 5.431 to about 5.657 angstroms, depending on the concentration of germanium in silicon-germanium. A compressive strain induced on the channel region 208 in the source 217 and drain 211 direction leads to an increase in the drive current of the PMOS transistor enabling the PMOS transistor to deliver a higher charging current from the power supply V_{DD} to the output terminal V_{OUT}. A higher charging current leads to a smaller propagation delay t_{pLH} associated with the PMOS transistor 202. A reduced t_{pLH} leads to a reduced inverter 200 delay and improved inverter 200 circuit performance.

In the second preferred embodiment shown in FIG. 2b, a PMOS 205 is coupled to strained channel NMOS transistor 207 to form an inverter 200. A second stressor 234 comprising a third semiconductor material occupies a region proximate the sides of the NMOS channel 209 and comprises a significant portion of the NMOS source 216 and NMOS drain 210 regions. Lattice-mismatch zones 241 define the junction of the first 226 and third 234 semiconductor materials in the strained channel NMOS transistor 207.

The third semiconductor material in the second stressor 234 may comprise an alloy semiconductor material such as silicon-germanium-carbon (Si_{1-x-y}GeₓC_{y}) or silicon carbon (Si_{1-y}C_{y}). The lattice constant of SiGeC can be smaller than that of silicon if the concentration of carbon is more than a tenth of that of germanium. The lattice-mismatched zones 241 may also comprise a semiconductor such as silicon-carbon (Si_{1-y}C_{y}), which has a lattice constant smaller than that of silicon. The mole fraction of carbon in Si_{1-y}C_{y} may vary from about 0.01 to about 0.04.

Lattice-mismatched zones 241 having a second stressor 234 comprised of a third semiconductor material with a smaller lattice constant than the first semiconductor material 226 exert a tensile stress in the channel region 209, resulting in a tensile strain across the lattice of the first semiconductor material 226 in the NMOS channel region 209. Tensile strain in the source 216 to drain 210 direction (i.e., a direction that is parallel to a line drawn from the source to the drain) enhances the mobility of electrons in the strained channel NMOS transistor 207, enabling the NMOS transistor 201 to deliver a higher discharging current when discharging the output terminal V_{OUT} to ground. A higher current discharge leads to a smaller propagation delay t_{pHL} associated with the NMOS transistor 207. A reduced t_{pHL} leads to a reduced inverter 200 delay and improved inverter 200 performance.

In the third preferred embodiment a strained channel PMOS 202 is coupled to strained channel NMOS transistor 207 to form an inverter, shown in FIG. 2c. A first stressor 222 occupies a region proximate the sides of the PMOS channel 208 and comprises a non-negligible portion of the PMOS source 217 and PMOS drain 211 regions. Lattice-mismatch zones define the junction of the first 226 and second 222 semiconductor materials in the PMOS transistor 202. The second stressor 234 occupies a region proximate the sides of the NMOS channel 209 and comprises a significant portion of the NMOS source 216 and NMOS drain 210 regions. Lattice-mismatch zones define the junction of the first 226 and second 234 semiconductor materials in the NMOS transistor 207.

As described above, a compressive strain induced on the PMOS channel region 208 leads to an increased drive current of the PMOS transistor 202 and the tensile strain induced on the NMOS channel region 209 leads to a higher discharging current of the NMOS transistor 207. A higher drive current of the PMOS transistor reduces t_{pLH} as described above, and a higher discharging current of the NMOS transistor 201 reduces t_{pHL} as described above, improving inverter 200 performance significantly.

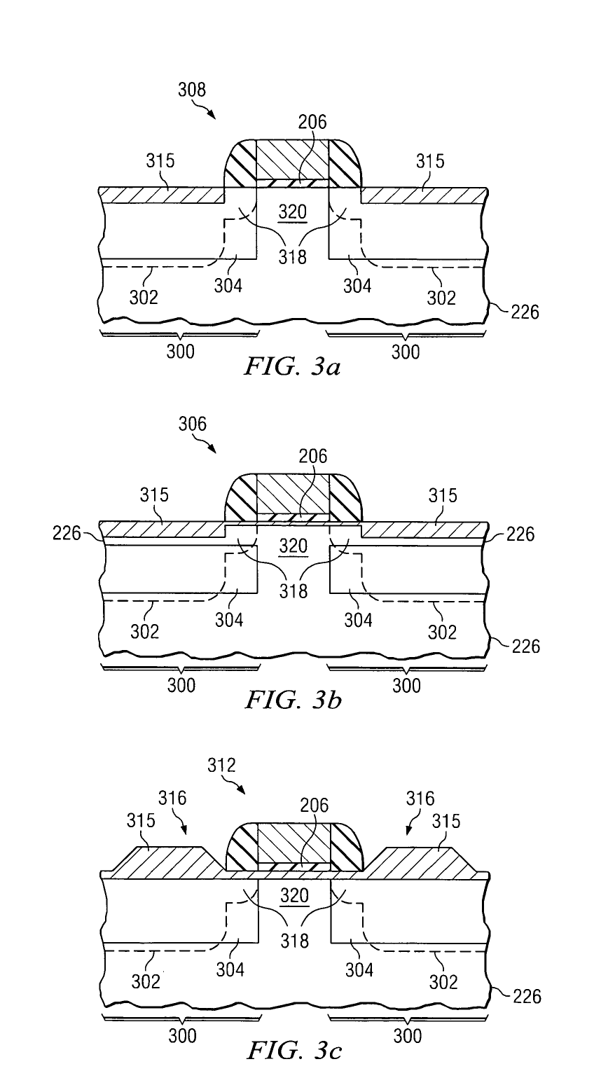

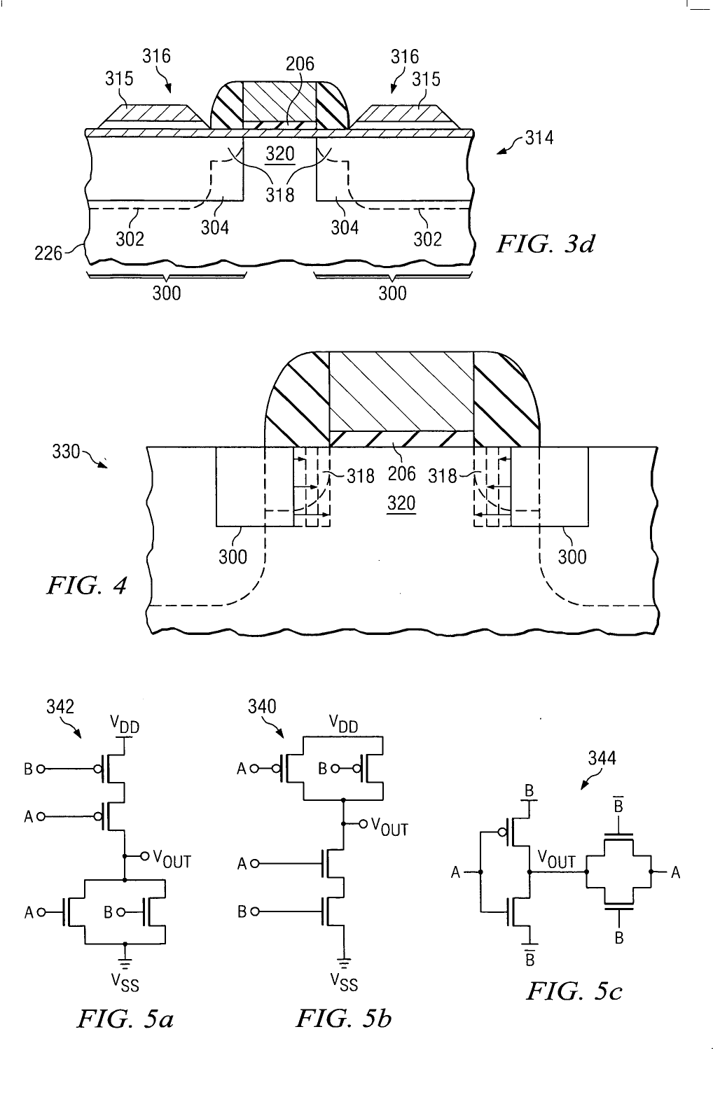

FIGS. 3a-3d, also collectively referred to herein as FIG. 3, show multiple embodiments of stressor placement in strained channel transistors 306, 308, 312 and 314. The first and second stressors are represented with a single reference numeral 300. The strained transistors 306, 308, 312, 314 in FIG. 3 are representative of the strained NMOS transistor 207 and the strained PMOS transistor 202, and the source and drain regions 300 are representative of the strained NMOS 207 source and drain regions 210 and 216 and strained PMOS 202 source and drain regions 211 and 217, respectively.

In FIG. 3, the location of the stressor 304 is meant to be illustrative and not meant to be restrictive. FIG. 3 shows that the location of the stressor 304 can be in any portion of the source or drain regions 300. In the case that the stressor 304 is slightly buried, such as the case shown in FIG. 3b, the stressor 300 may be capped with a layer of silicon 226 preferably with the first semiconductor material or the like.

A conductive material 315, shown in FIG. 3, such as a metal silicide (e.g., titanium silicide, cobalt silicide, nickel silicide, tantalum silicide, erbium silicide, iridium silicide), may be strapped to the source and drain regions 300 to reduce contact resistance. Other materials include cobalt germanosilicide, nickelgermanosilicide, cobalt carbon-silicide, nickel carbon-silicide. The silicide may be in the substrate and below the level of the gate dielectric as shown in FIGS. 3a and 3b, or extend above the level of the gate dielectric as shown in FIGS. 3c and 3d. The stressor 304 may evenly extend above the level of the gate dielectric 206 to form a raised portion source and drain regions. FIG. 3d shows the stressor 304 comprised below the substrate surface 226 and the first semiconductor material above the substrate surface 226 and in between a metal silicide 315 and the stressor 304.

Furthermore, the stressor 300 may or may not be extended horizontally into the source extension region or the drain extension region 318 as illustrated in FIG. 4. As shown in the transistor 330, the proximity of the stressor to the channel region 320 may vary according to desired device performance characteristics. Forming the stressor 300 as close as possible to the channel region enhances the electron or hole mobility of the transistor 330.

FIGS. 5a-5c show example circuit schematics of multiple embodiments, e.g. NOR gate 342 (FIG. 5a), NAND gate 340 (FIG. 5b), XOR gate 344 (FIG. 5c), comprising the present invention. These embodiments are included to show several circuits that can utilize concepts of the present invention. For example, the PMOS transistors can be strained channel transistors (see e.g., FIG. 2a) while the NMOS transistors are not strained. In another example, the NMOS transistors are strained while the PMOS transistors are not (see e.g., FIG. 2b). Finally, as disclosed with respect to the embodiment of FIG. 2c, both the NMOS and PMOS transistors can be strained. These examples are meant to be illustrative and not meant to be restrictive or limiting in scope.

In one aspect, the present invention teaches a method of integrating strained channel transistors of more than one conduction type with minimal degradation of carrier mobility to transistors of the other conductivity type. The circuits of FIGS. 5a-5c provide examples of circuits that can utilize these advantages.

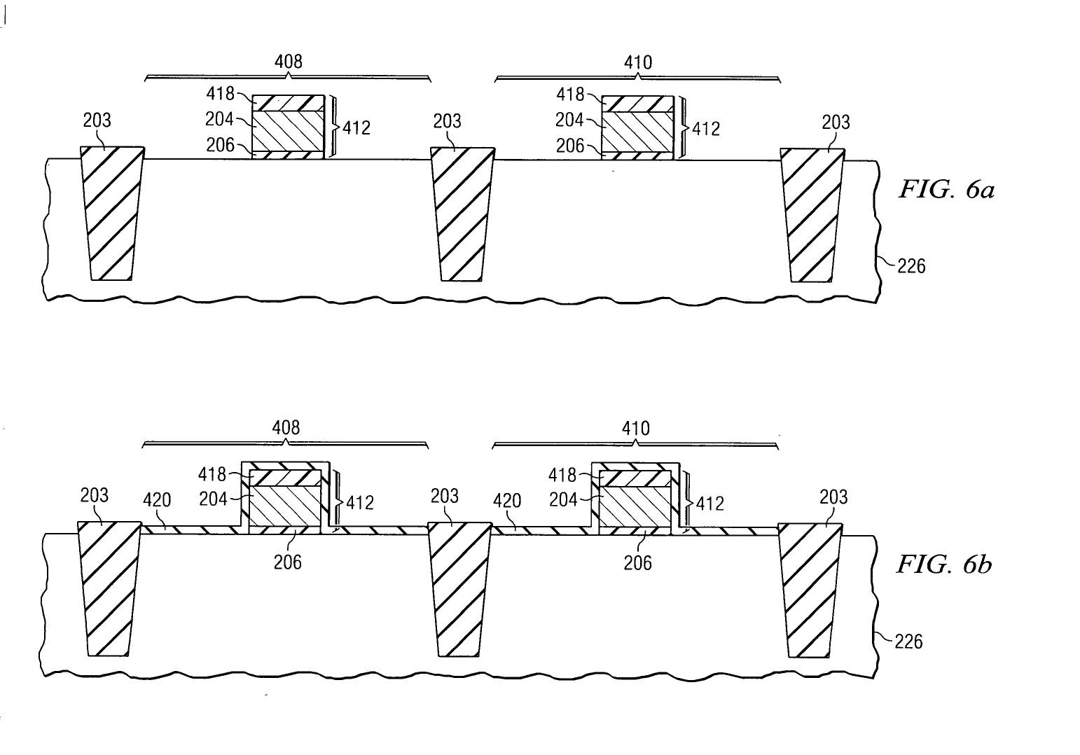

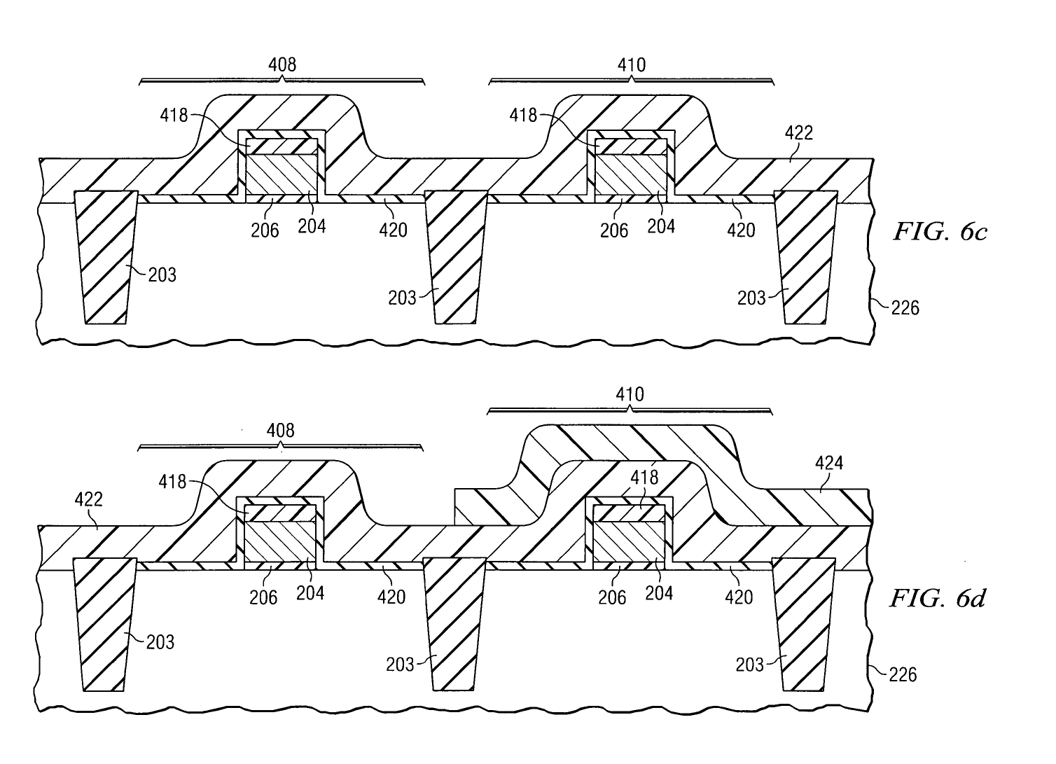

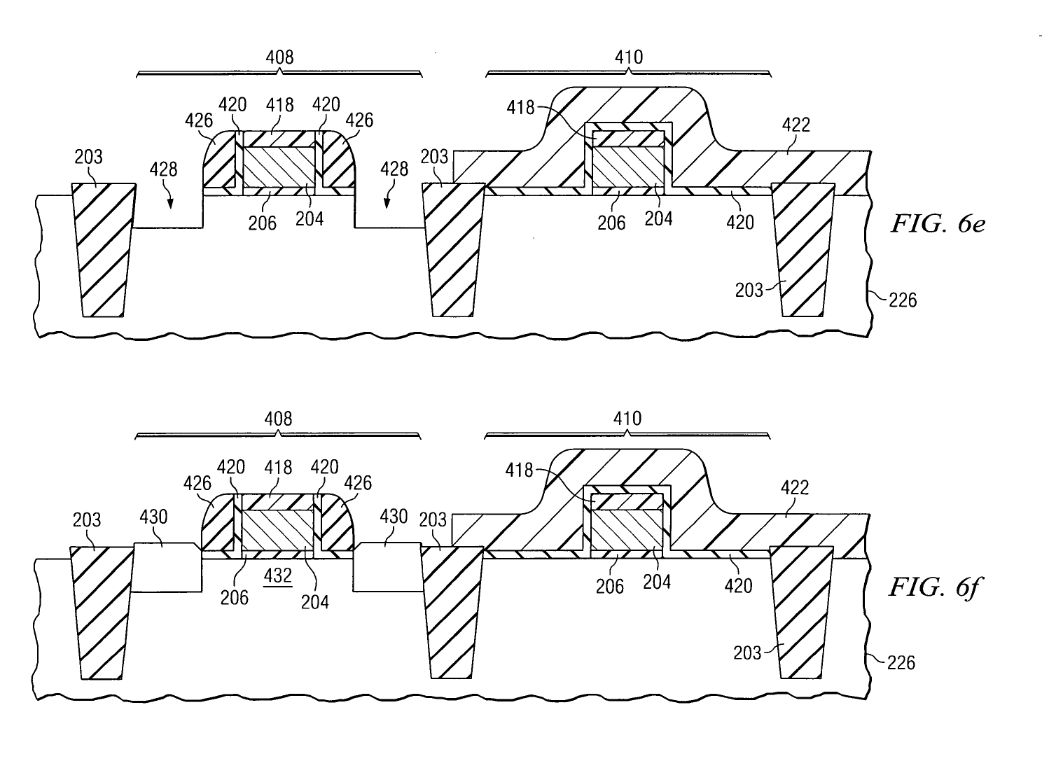

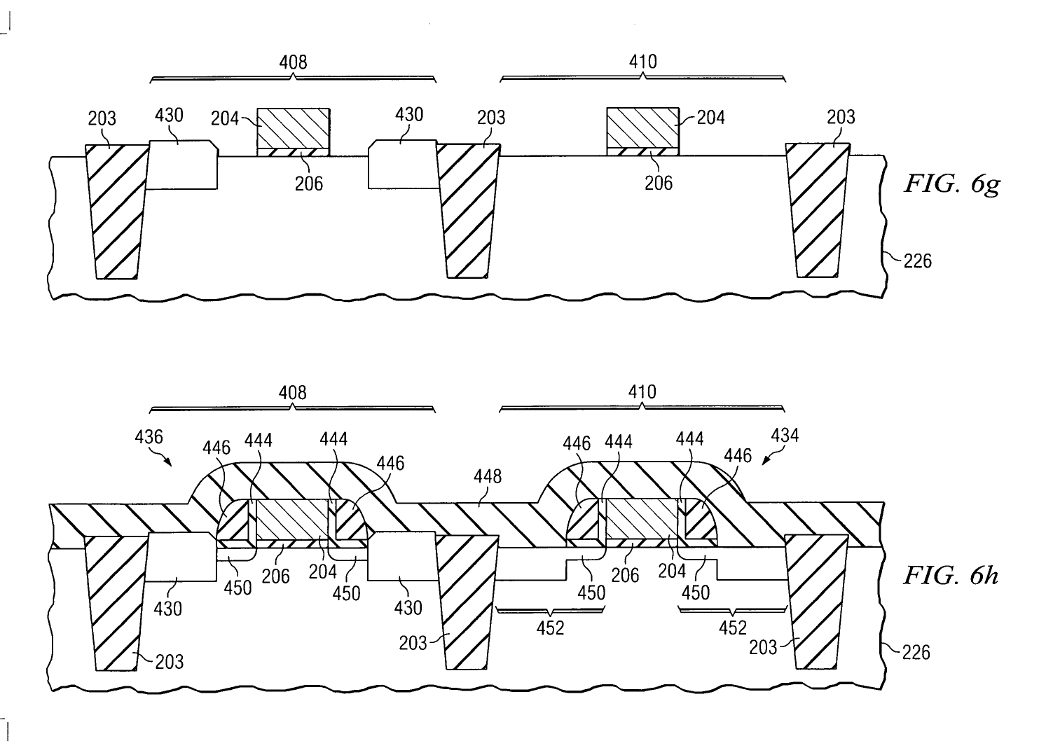

Referring now to FIGS. 6a-6h, a method of manufacturing an integrated circuit with strained channel transistors of multiple conduction types, is described. A semiconductor substrate 226, preferably a silicon substrate, is provided and isolation structures 203 are formed to define active regions in the substrate. The isolation structures 203 may be formed using standard shallow trench isolation (STI) processes, for example, comprising the steps of etching trenches with depths in the range of about 2000 to about 6000 angstroms, filling the trenches with a trench filling dielectric material by chemical vapor deposition, and performing a chemical mechanical planarization to give the cross-section as shown in FIG. 6a. It is understood, however, that other isolation structures, such as field oxide (e.g., formed by the local oxidation of silicon) may be used.

FIG. 6a shows a gate stack 412 formed in the first and second active regions 408/410. The gate stack 412 may comprise a hard mask 418, a gate electrode 204 and a gate dielectric 206. A hard mask 418 forms a protective layer on the top of the gate electrode 204. The gate electrode 204 overlies the gate dielectric 206. The gate dielectric 206 is formed using any gate dielectric formation process known and used in the art, e.g., thermal oxidation, nitridation, sputter deposition, or chemical vapor deposition. The physical thickness of the gate dielectric 206 may be in the range of about 5 to about 100 angstroms. The gate dielectric 206 may employ a conventional gate dielectric such as silicon oxide and silicon oxynitride or a high permittivity (high-k) gate dielectric, or combinations thereof.

As shown in FIG. 6b, a disposable film 420 is formed over the first and second active regions 408/410. The disposable film may be a dielectric film formed using a chemical vapor deposition process or sputter deposition. The disposable film may comprise oxide, for example. In the preferred embodiment, the disposable film 420 is between about 20 and about 1000 angstroms thick.

Referring now to FIG. 6c, a first mask material 422 is deposited over the first and second active regions 408/410. This material 422 may be silicon oxide, silicon oxynitride, or silicon nitride, as examples. In the preferred embodiment, the first mask material 422 comprises a silicon nitride on a silicon oxide multi-layer.

FIG. 6d shows a second mask material 424 formed over the second active region 410 using deposition and photolithographic techniques to cover the first mask material 422 in the second active region 410, while exposing the first mask material 422 in the first active region. The second mask material 424 may comprise any masking material that is different from the first mask material 422. In the preferred embodiment, the second mask material comprises a photoresist.

An etching of the first mask material 422 in the second active region 410 takes place in the presence of the second mask material 424. The etching is preferably an anisotropic etch done using plasma etching techniques. This results in disposable spacers or liners 426 being formed adjacent to the gate stack 412 in the first active region 408.

After the disposable spacers 426 are formed, recessed regions 428 are etched in the active area substantially aligned with the disposable spacers 426. A silicon etch chemistry can be used as discussed above. The second mask material 424 may be removed after etching.

Next, the second semiconductor material 430 is epitaxially grown to at least partially fill the recessed region 428. This can be accomplished using selective epitaxial growth (SEG). The epitaxy process used to perform the epitaxial growth may be chemical vapor deposition (CVD), ultra-high vacuum chemical vapor deposition (UHV-CVD), or molecular beam epitaxy (MBE). The epitaxially grown materials may also extend above the surface of the channel region 432 of the first active region 408, forming a raised source and drain 430 structure as shown in FIG. 6f.

The second semiconductor material 430 may comprise silicon germanium with a germanium mole fraction between about 0.1 and about 0.9. The second semiconductor may otherwise comprise a material such as silicon-carbon Si_{1-y}C_{y} with a carbon mole fraction of between about 0.01 and about 0.04. Alternatively, the second semiconductor may comprise silicon-germanium-carbon (Si_{1-x-y}GeₓC_{y}). The lattice constant of SiGeC can be smaller than that of silicon if the concentration of carbon is more than a tenth of that of germanium.

The hard mask 418 covers the top portion of the gate electrode 204 so that no epitaxial growth occurs on the gate electrode 204. The disposable spacer 426 prevents epitaxial growth on the gate electrode 204 sidewalls. Following epitaxial growth, the hard mask 418, disposable film 420, disposable spacer 426 and first mask material 422 may be removed, forming the structure shown in FIG. 6g.

The epitaxially grown first semiconductor material 226 may be in-situ doped or undoped during the epitaxial growth. If undoped as grown, it may be doped subsequently and the dopants activated using a rapid thermal annealing process. The dopants may be introduced by conventional ion implantation, plasma immersion ion implantation (PIII), gas or solid source diffusion, or any other techniques known and used in the art. Any implant damage or amorphization can be annealed through subsequent exposure to elevated temperatures.

FIG. 6h shows the semiconductor device after further processing. A first shallow implantation can be performed on the structure of FIG. 6g to dope the shallow regions 450 of the first and second transistor source and drain regions 452 and to form the source/drain extensions.

Spacers are formed on the sidewalls of the gate electrode 204. In one example, the spacers may be formed by chemical vapor deposition of a dielectric material, e.g., silicon oxide or silicon nitride, followed by an anisotropic etching of the dielectric material to form simple spacers. In the example of FIG. 6h, the spacers are composite spacers. A composite spacer may comprise a dielectric liner 444 and a spacer body 446. The dielectric liner 444 may be formed by the deposition of a dielectric liner material, e.g., silicon oxide, and the spacer body material 446, e.g. silicon nitride, followed by an anisotropic etch using reactive ion etching. In another embodiment, the liner 444 may be an oxide and the spacer body 446 may be a nitride.

The source and drain regions for the first transistor 436 are formed using ion implantation while covering the second transistor 434. In the preferred embodiment, the dopant is arsenic or phosphorus or a combination of both. The source and drain regions for the second transistor 434 are formed by using ion implantation while covering the first transistor 436. In the preferred embodiment, a dopant such as boron is used. A passivation layer 448 is formed over the first and second active regions 408/410.

Other methods and variations of forming a structure are disclosed in co-pending application Serial No.______ (TSM03-0615), which is incorporated herein by reference. The methods and variations taught in that application can be applied to the structures disclosed herein. For the sake of simplicity, each of these variations will not be repeated herein.

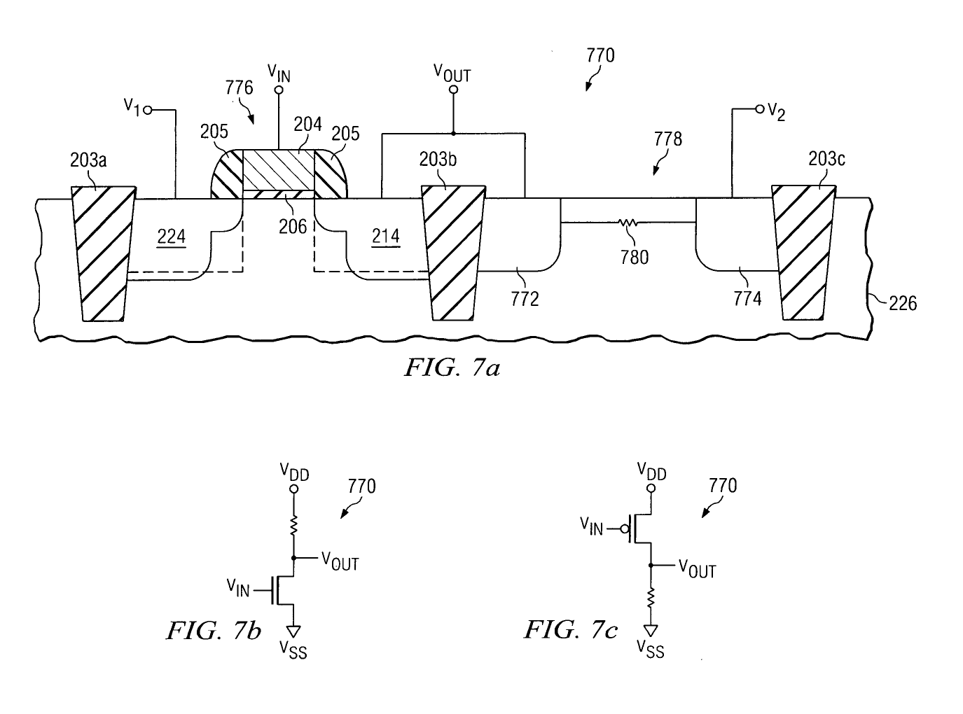

FIGS. 7a-7c show an alternate embodiment inverter. In this example, the inverter 770 includes a strained channel transistor 776 coupled in series with a resistor 778. While a transistor served as the load element in FIG. 2, in this example the resistor 778 is the load element. The strained channel transistor 776 can be either an NMOS transistor (FIG. 7b) or a PMOS transistor (FIG. 7c). The choice will typically depend upon which conductivity type transistors are being formed elsewhere on the chip.

As shown in FIG. 7a, the resistor 778 includes a resistive portion 780 separating two highly doped terminal portions 772 and 774. The terminal portion 772 is coupled to source/drain region 214 of transistor 776. In the illustrated example, an isolation trench 203b is shown between regions 214 and 772. In some instances, e.g., when regions 214 and 772 are of the same conductivity type, the isolation trench 203b can be eliminated thereby reducing the surface area.

The second terminal 774 is coupled to a voltage Supply V₂. In the example of FIG. 7b, the supply voltage node V₂ is the supply node V_{DD} and the supply voltage node V₁ is the supply node V_{SS} (e.g., ground). In the example of FIG. 7c, the supply voltage node V₂ is the supply node V_{SS} and the supply voltage node V₁ is the supply node V_{DD}. While not shown, other components, e.g., a transistor, can be coupled between the supply nodes V₁, V₂ and the inverter components 776 and 778.

In another embodiment, the resistor 778 may be a resistor of the type taught in co-pending application Ser. No. 10/667,871, filed Sep. 22, 2003 (TSM03-0553), which application is incorporated herein by reference.

Although the present invention and its advantages have been described in detail, it should be understood that various changes, substitutions and alterations can be made herein without departing from the spirit and scope of the invention as defined by the appended claims. As another example, it will be readily understood by those skilled in the art that the structure and method of forming integrated circuits utilizing strained channel transistors may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor structure comprising:
a semiconductor substrate that includes a first semiconductor material and a second semiconductor material wherein the first semiconductor material has a lattice constant that is different from a lattice constant of the second material;
a first transistor formed in the semiconductor substrate, the first transistor having first source and drain regions formed in the substrate oppositely adjacent a first channel region, wherein a first gate dielectric overlies the first channel region and a first gate electrode overlies the first gate dielectric, and wherein the first channel region is formed in the first semiconductor material and at least a portion of the first source and drain regions are formed in the second semiconductor material; and
a second transistor formed in the semiconductor substrate, having a conductivity type different than the first transistor, the second transistor having second source and drain regions in the substrate oppositely adjacent a second channel region, wherein a second gate dielectric covers the second channel region and a second gate electrode covers the second gate dielectric.

2. The structure of claim 1 wherein the first transistor is coupled to the second transistor to form an inverter.

3. The structure of claim 1 wherein the first transistor is coupled to the second transistor as part of a NOR circuit.

4. The structure of claim 1 wherein the first transistor is coupled to the second transistor as part of a NAND circuit.

5. The structure of claim 1 wherein the first transistor is coupled to the second transistor as part of an XOR circuit.

6. The structure of claim 1 wherein the first and second gate dielectrics are formed from a high-k dielectric.

7. The structure of claim 1 wherein the first and second gate electrodes comprise a metal material.

8. The structure of claim 1 wherein the lattice constant of the second semiconductor material is larger than the lattice constant of the first semiconductor material.

9. The structure of claim 8 wherein the first transistor is a PMOS transistor.

10. The structure of claim 9 wherein the second semiconductor material comprises silicon (Si) and germanium (Ge).

11. The structure of claim 10 wherein the second semiconductor material comprises Silicon (Si), Germanium (Ge), and Carbon (C).

12. The structure of claim 10 wherein the concentration of Ge is greater than 10 percent.

13. The structure of claim 1 wherein the lattice constant of the second semiconductor material is smaller than the lattice constant of the first semiconductor material.

14. The structure of claim 13 wherein the first transistor is an NMOS transistor.

15. The structure of claim 14 wherein the second semiconductor material comprises silicon and carbon.

16. The structure of claim 15 wherein the second semiconductor material comprises silicon, germanium, and carbon.

17. The structure of claim 15 wherein the concentration of carbon is in the range of 0.01 percent to 0.04 percent.

18. The structure of claim 1 further comprising a third semiconductor material, wherein at least a portion of the second source and drain regions are formed in the third semiconductor material.

19. The structure of claim 18 wherein the lattice constant of the second semiconductor material is larger than lattice constant of the first semiconductor material and the lattice constant of the third material is smaller than the lattice constant of the first material.

20. The structure of claim 19 wherein the first transistor is a PMOS and the second transistor is an NMOS.

21. The structure of claim 19 wherein the third semiconductor material comprises silicon, germanium and carbon.

22. The structure of claim 1 wherein the first transistor comprises a PMOS transistor and the second transistor comprises an NMOS transistor and wherein the ratio of a width of the gate of the PMOS transistor to a width of the gate of the NMOS transistor is approximately equal to the square root of a ratio of electron mobility to the hole mobility in the channel region.

23. The structure of claim 1 wherein the first transistor comprises a PMOS transistor and the second transistor comprises an NMOS transistor and wherein the ratio of a width of the gate of the PMOS transistor to a width of the gate of the NMOS transistor is approximately equal to the ratio of electron mobility to hole mobility in the channel region.

24. The structure of claim 1 wherein the first and second source and drain regions and the gate electrodes of the first and second transistors each include a silicided portion.

25. The structure of claim 1 wherein the distance between a junction between the first semiconductor material and the second semiconductor material and the gate dielectric edge is less than 700 angstroms.

26. An inverter comprising:
a transistor formed in the semiconductor substrate, the transistor having a source region and a drain region formed in a semiconductor substrate oppositely adjacent a channel region, wherein the channel is formed in a first semiconductor material and at least a portion of the source region and the drain region is formed in a second semiconductor material, the first semiconductor material being different than the second semiconductor material;
a load element formed in the semiconductor substrate, the load element coupled between the drain region and a first supply voltage node; and
a second supply voltage node coupled to the source region.

27. The inverter of claim 26 wherein the load element comprises a resistor and the transistor comprises an NMOS transistor.

28. The inverter of claim 26 wherein the load element comprises a resistor and the transistor comprises a PMOS transistor.

29. The inverter of claim 26 wherein the load element comprises a transistor.

30. The inverter of claim 29 wherein the load element comprises a strained transistor.

31. The inverter of claim 26 wherein the transistor includes a gate dielectric overlying the channel region, the gate dielectric being formed from a high-k dielectric.

32. The inverter of claim 31 wherein the transistor includes a gate electrode overlying the gate dielectric, the gate electrode comprising a metal material.

33. The inverter of claim 26 wherein a lattice constant of the second semiconductor material is larger than a lattice constant of the first semiconductor material.

34. The inverter of claim 33 wherein the transistor is a PMOS transistor.

35. The inverter of claim 34 wherein the second semiconductor material comprises silicon (Si) and germanium (Ge).

36. The inverter of claim 35 wherein the concentration of Ge is greater than 10 percent.

37. The inverter of claim 26 wherein the lattice constant of the second semiconductor material is smaller than the lattice constant of the first semiconductor material.

38. The inverter of claim 37 wherein the transistor is an NMOS transistor.

39. The inverter of claim 38 wherein the second semiconductor material comprises silicon (Si), germanium (Ge), and carbon (C).

40. The inverter of claim 39 wherein the concentration of carbon is in the range of 0.01 percent to 0.04 percent.

41. The inverter of claim 26 wherein the first and second source and drain regions and the gate electrodes of the first and second transistors each include a silicided portion.

42. The inverter of claim 26 wherein the first semiconductor material consists essentially of silicon.

43. The inverter of claim 42 wherein the second semiconductor material comprises silicon and germanium.

44. The inverter of claim 42 wherein the second semiconductor material comprises silicon and carbon.

45. The inverter of claim 26 wherein the semiconductor substrate further comprises an insulator layer underlying the first semiconductor material.

46. The inverter of claim 26 and further comprising a conductive material formed over the source region and the drain region.

47. The inverter of claim 46 wherein the conductive material at least one material selected from the group consisting of titanium silicide, cobalt silicide, nickel silicide, tantalum silicide, erbium silicide, iridium silicide, cobalt germanosilicide, nickel germanosilicide, cobalt carbon-silicide, nickel carbon-silicide.

48. The inverter of claim 26 wherein the transistor comprises a gate dielectric overlying the channel region and a gate electrode overlying the gate dielectric, the gate electrode being formed from a semiconductor.

49. The inverter of claim 48 wherein the gate electrode is formed from polycrystalline silicon.

50. The inverter of claim 26 wherein the transistor comprises a gate dielectric overlying the channel region and a gate electrode overlying the gate dielectric, the gate electrode being formed from a metal.

51. The inverter of claim 26 wherein the transistor comprises a gate dielectric overlying the channel region and a gate electrode overlying the gate dielectric, the gate electrode being formed from a metal silicide.

52. The inverter of claim 26 wherein the transistor comprises a gate dielectric overlying the channel region and a gate electrode overlying the gate dielectric, the gate electrode being formed from a metal nitride.

53. The inverter of claim 26 wherein the transistor comprises a gate dielectric overlying the channel region and a gate electrode overlying the gate dielectric, wherein the gate dielectric comprises at least one material selected from the group consisting of silicon oxide, silicon oxynitride, and silicon nitride.

54. The inverter of claim 26 wherein the transistor comprises a gate dielectric overlying the channel region and a gate electrode overlying the gate dielectric, wherein the gate dielectric comprises a high k dielectric.

55. The inverter of claim 54 wherein the gate dielectric comprises at least one material selected from the group consisting of hafnium oxide, aluminum oxide, and zirconium oxide, and combinations thereof.

56. A method of forming a semiconductor structure, the method comprising:
providing a semiconductor substrate that includes a semiconductor body formed of a first semiconductor material;
defining a first active area and a second active area in the semiconductor body;
forming a first transistor in the first active area, the first transistor including a source region and a drain region formed in the semiconductor body oppositely adjacent a channel region, the first transistor further including a gate dielectric overlying the channel region and a first gate electrode overlying the first gate dielectric, wherein the first channel region is formed in the first semiconductor material and at least a portion of the source region and the drain region is formed in a second semiconductor material, the second semiconductor material having a lattice constant that is different than a lattice constant of the first semiconductor material;
forming a second element in the second active area; and
forming a conductor between the drain of the transistor and the load element.

57. The method of claim 56 wherein the second element comprises a second transistor including a conductivity type different than that of the first transistor, the second transistor having second source and drain regions in the substrate oppositely adjacent a second channel region, wherein the conductor is formed between the drain the first transistor and the drain of the second transistor.

58. The method of claim 57 and further comprising:
electrically coupling the source of the first transistor to a first supply voltage node; and
electrically coupling the source of the second transistor to a second supply voltage node.

59. The method of claim 56 wherein the second element comprises a resistor.

60. The method of claim 59 wherein the resistor comprises a first terminal and a second terminal such that the conductor is formed between the drain of the transistor and the first terminal of the resistor, the method further comprising:
electrically coupling the source of the first transistor to a first supply voltage node; and
electrically coupling the second terminal of the resistor to a second supply voltage node.

61. The method of claim 56 wherein forming a first transistor comprises:
forming a gate stack that includes the gate dielectric and the gate electrode;
forming a dielectric layer over the first active area including the gate stack;
anisotropically etching the dielectric layer to form sidewall spacers along sidewalls of the gate electrode;
etching a portion of the semiconductor body to form trenches adjacent the sidewall spacers; and
forming the second semiconductor material in the trenches.

62. The method of claim 61 and further comprising implanting dopants through the second semiconductor material and into the semiconductor body to form the source and drain regions.

63. The method of claim 62 wherein the source and drain regions extend at least 1000 angstroms into the semiconductor body.

64. The method of claim 63 wherein the second semiconductor material has thickness of less than about 200 angstroms.

65. The method of claim 61 and further comprising forming a layer of the first semiconductor material over the second semiconductor material.

66. The method of claim 61 wherein forming a gate stack further comprises forming a second gate stack over the second active area and wherein forming a dielectric layer comprises forming a dielectric layer over the first active area and the second active area.

67. The method of claim 66 and further comprising forming a mask over the second active area after forming the dielectric layer but before anisotropically etching.

68. The method of claim 56 wherein the lattice constant of the second semiconductor material is larger than the lattice constant of the first semiconductor material.

69. The method of claim 68 wherein the first transistor is a PMOS transistor.

70. The method of claim 69 wherein the second semiconductor material comprises silicon and germanium.

71. The method of claim 70 wherein the second semiconductor material comprises silicon, germanium, and carbon.

72. The method of claim 70 wherein the concentration of germanium is greater than 10 percent.

73. The method of claim 56 wherein the lattice constant of the second semiconductor material is smaller than the lattice constant of the first semiconductor material.

74. The method of claim 73 wherein the first transistor is an NMOS transistor.

75. The method of claim 74 wherein the second semiconductor material comprises silicon and carbon.

76. The method of claim 75 wherein the second semiconductor material comprises silicon, germanium, and carbon.

77. The method of claim 75 wherein the concentration of carbon is in the range of 0.01 percent to 0.04 percent.
